(19) United States
(12) Patent Application Publication
(10) Pub. No.: US 2006/0212768 A1
(43) Pub. Date: Sep. 21, 2006

(54) Verification circuitry for master-slave system

(75) Inventor: Keitaro Ishida, Tokyo (JP)

Correspondence Address: NIXON PEABODY, LLP, 401 9TH STREET, NW, SUITE 900, WASHINGTON, DC, 20004-2128, US

(73) Assignee: Oki Electric Industry Co., Ltd., Tokyo (JP)

(21) Appl. No.: 11/349,888

(22) Filed: Feb. 9, 2006

(30) Foreign Application Priority Data
Mar. 11, 2005 (JP) 2005-068965

(51) Int. Cl. G01R 31/28

(52) U.S. Cl. 714/733

(57) ABSTRACT

Operation of a system including master and slave devices is verified through the use of system verification circuitry including a test master circuit that outputs test patterns on the system bus to emulate the operation of all master devices in the system, a built-in self-test and memory circuit that stores the test patterns and expected responses and compares the expected responses with the responses produced by the test patterns, and an interface circuit through which a host system downloads the test patterns and expected response values into the built-in self-test and memory circuit. Use of the test master circuit enables system and bus protocol features to be exercised fully without constraints arising from the limited capabilities of any one master device. The verification circuitry can be usefully incorporated together with the master and slave devices into a prototype system on a chip.

### BACKGROUND OF THE INVENTION

1. Field of the Invention

The present invention relates to circuitry for verifying the operation of a computing system including master and slave devices, more particularly a system including multiple master devices.

2. Description of the Related Art

A computing system these days is likely to include a number of devices combined into a field-programmable gate array (FPGA) or some other type of application-specific integrated circuit (ASIC) as a system on a chip. FIG. 1 shows a simplified example of an FPGA 1 including two master devices and two slave devices. The master devices, also referred to below as masters, are a central processing unit (CPU) 2 and a direct memory access (DMA) device 3. The masters are interconnected to each other and to the slave devices (slaves) 4, 5 by a high-speed bus 6. Either master can take control of the bus 6 to access one of the slaves or an external device such as a memory device (not shown). The slaves respond to access by the masters but do not initiate bus transactions themselves. In communicating over the bus, the masters follow a standardized protocol that allows for different types of access, typically including both fixed-size and incremental-size data transfers, and burst transfers to sequential addresses.

At various stages during the development of this type of system it is necessary to verify that the system will work. It would be convenient if such verification could be performed entirely by simulation on a computer, but in a system including multiple devices, the time needed to execute the simulation becomes prohibitive. An alternative method is to prototype the system and test the prototype.

FIG. 2 shows an example in which a prototype version of the FPGA 1 in FIG. 1, an input/output (I/O) interface unit 7, and an external memory unit 8 are mounted on a printed circuit board 9 that can be connected to a host computer system such as a workstation equipped with debugging software. The host system transfers test pattern data for the target system (the FPGA 1) to the prototype board 9, each test pattern specifying a pattern of signals to be output by a master device on the bus 6. The test patterns are executed and checked to see whether each elicits the expected pattern of response signals.

One problem with this testing scheme is that the CPU 2 and other master devices in the FPGA 1 are normally designed for a specific application and do not have space for storing test pattern data. The test patterns must accordingly be stored in the external memory 8, or in a slave memory in the FPGA 1, and read by one of the master devices. This involves the execution of a number of instructions by the CPU 2; these instructions must also be read from a memory device. The overhead of reading the test pattern data and instructions and executing the instructions makes it difficult to conduct a realistic test of a system function that involves a continuous sequence of operations.

Another problem is that because each master device implements only the features needed in the target system, usually no one master is capable of performing all the types of bus access that may occur in the system. For example, if the CPU 2 always performs fixed-size data transfers, it may be difficult or impossible to test incremental-size data transfers performed by the DMA device 3.

A further problem is that when a test uncovers a fault, the overhead mentioned above complicates the analysis of the fault. Detailed analysis requires a computer simulation, reproducing the exact conditions that led up to the fault, but because of the overhead on the bus 6, it can be difficult and time-consuming to determine what those conditions were.

These problems also occur when an application-specific integrated circuit is prototyped as plurality of separate chips, typically including FPGAs, memory chips, and a CPU chip, or as a plurality of chips and an in-circuit emulator (ICE).

International patent application No. WO 01/73459 A2 discloses a system and method for testing signal interconnections by placing built-in self-test (BIST) circuitry in each component integrated circuit chip, but the BIST circuitry must generate its own test patterns and responses, and is limited to testing external interconnections.

### SUMMARY OF THE INVENTION

A general object of the present invention is to simplify the testing of complex systems implemented in integrated circuit chips.

A more specific object is to enable an arbitrary sequence of test patterns to be executed without overhead in a complex integrated circuit.

Another more specific object is to facilitate the testing of different access patterns used by different master devices in a complex integrated circuit.

A further more specific object is to exercise all features of a bus protocol in a complex integrated circuit.

The invention provides system verification circuitry including a test master circuit, a built-in self-test and memory circuit, and a built-in self-test interface circuit for use in verifying the operation of a system in which a plurality of master devices and at least one slave device are connected to a system bus.

The test master circuit outputs test patterns on the system bus to verify the operation of the slave device(s) and receives response signals from the slave device(s).

The built-in self-test and memory circuit has an internal memory from which the test master obtains the test patterns, and a comparator that compares the response signals with expected values. The built-in self-test and memory circuit may also have a control circuit that controls the test master circuit according to the result of the comparison and stores the addresses of test patterns that lead to unexpected response signals.

The built-in self-test interface circuit receives the test patterns and expected values from an external source and stores them in the internal memory of the built-in self-test and memory circuit. The built-in self-test interface circuit may receive the test patterns and expected values via the system bus, or via a separate external interface.

The test master circuit is preferably capable of outputting any pattern of signals on the system bus that can be output by any of the master devices, or any pattern permitted by the bus protocol employed by the master devices. The test master circuit receives the test patterns directly from the built-in self-test and memory circuit, instead of receiving them over the system bus, and therefore operates without the overhead associated with bus transfer of test pattern data.

The master and slave devices and the system verification circuitry may be disposed together in a monolithic integrated circuit; alternatively, they may be divided among two or more monolithic integrated circuits.

### BRIEF DESCRIPTION OF THE DRAWINGS

In the attached drawings:

FIG. 1 is a block diagram of a conventional system on a chip including master and slave devices;

FIG. 2 is a block diagram showing the internal structure of a conventional prototype board;

FIG. 3 is a block diagram of a system including system verification circuitry according to a first embodiment of the invention;

FIG. 4 illustrates a bus protocol;

FIG. 5 is a block diagram schematically illustrating the internal structure of the test master circuit and built-in self-test and memory circuit in FIG. 3;

FIG. 6 shows a list of test patterns stored in the internal memory in FIG. 5;

FIG. 7 shows a concrete example of a list of test patterns and expected results; and

FIG. 8 is a block diagram of a system including system verification circuitry according to a second embodiment of the invention.

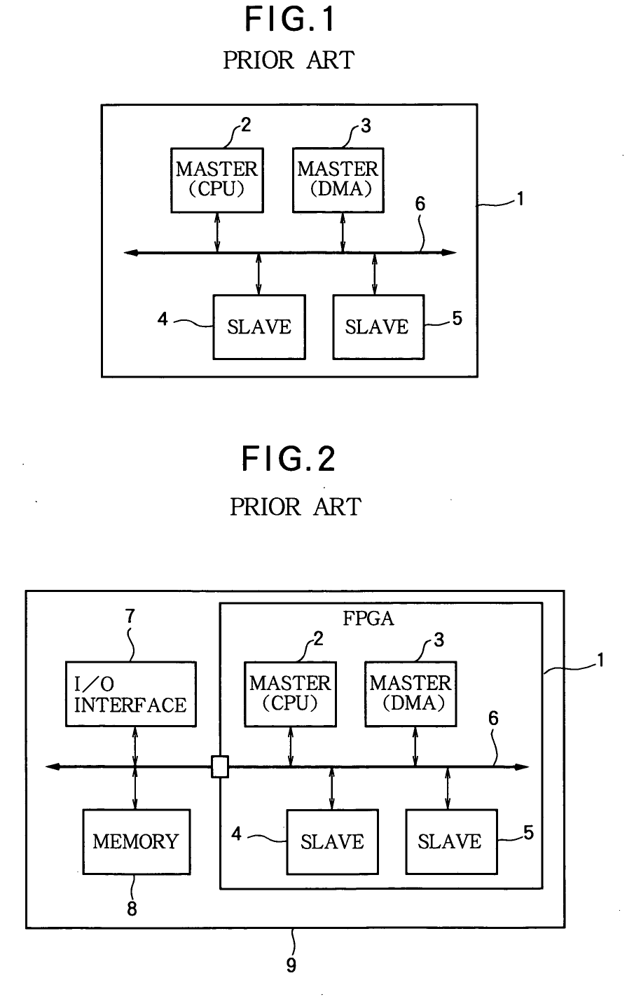

### DETAILED DESCRIPTION OF THE INVENTION

Embodiments of the invention will now be described with reference to the attached drawings, in which like elements are indicated by like reference characters.

### FIRST EMBODIMENT

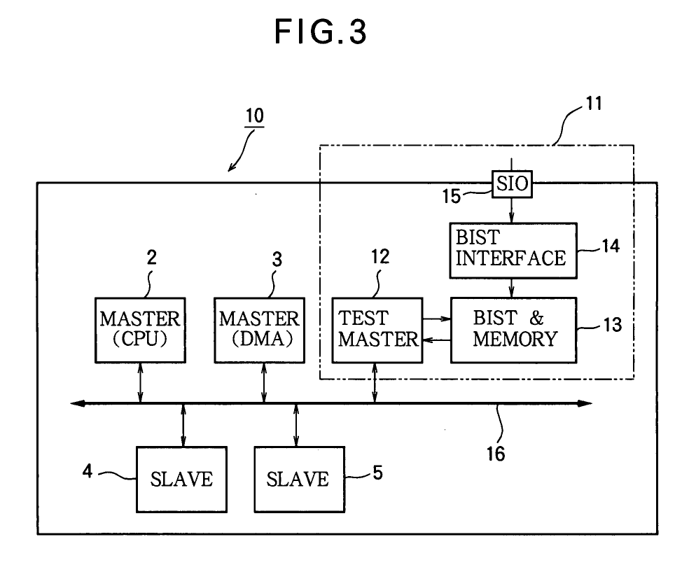

As a first embodiment, FIG. 3 shows a monolithic integrated circuit, more specifically an FPGA 10, including a CPU 2 and a DMA device 3 which operate as master devices, a pair of slave devices 4, 5, and system verification circuitry 11 embodying the present invention. The system verification circuitry 11 includes a test master circuit 12, a built-in self-test (BIST) and memory circuit 13, a built-in self-test interface circuit 14, and a serial interface 15. The test master circuit 12 is connected to the system bus 16 and operates as a master device to access the slave devices 4, 5 in the same way that the CPU 2 and DMA device 3 access them. If necessary, the test master circuit 12 can also access the DMA device 3 and CPU 2.

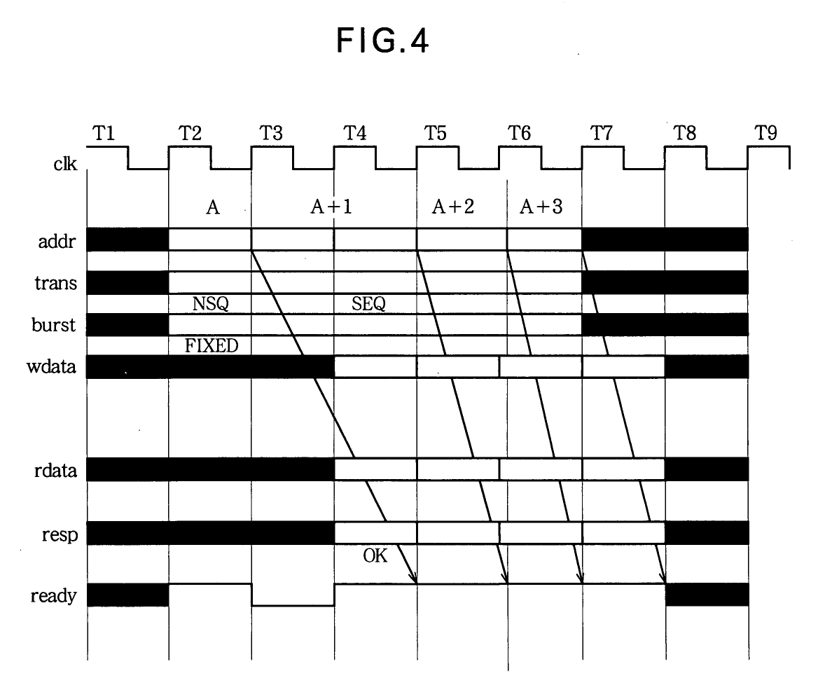

The system bus 16 interconnects the master devices 2, 3, 12 and slaves devices 3, 4 in the FPGA 10. The protocol used on the system bus 16 is illustrated in FIG. 4. Bus transfers are synchronized with a clock signal (clk). A master device outputs address signals (addr) and transfer type and size signals followed, when the addressed device is ready, by write data (wdata). The transfer type signal (trans) indicates whether the address is sequential (SEQ), that is, in sequence with the preceding address, or non-sequential (NSQ; the non-sequential case normally occurs at the beginning of a transfer sequence). The transfer size signal (burst) indicates whether the size of the transferred data is the predetermined size normally used on the system bus 16 (FIXED) or an incrementally variable size (INCR). Output of address signals and transfer type and size signals by the master constitutes a data transfer request.

A slave (or other master) device responds to a data transfer request with output of a ready signal, followed by read data (rdata) and a response (resp) signal indicating whether the transfer ended successfully (OK) or not (ERR).

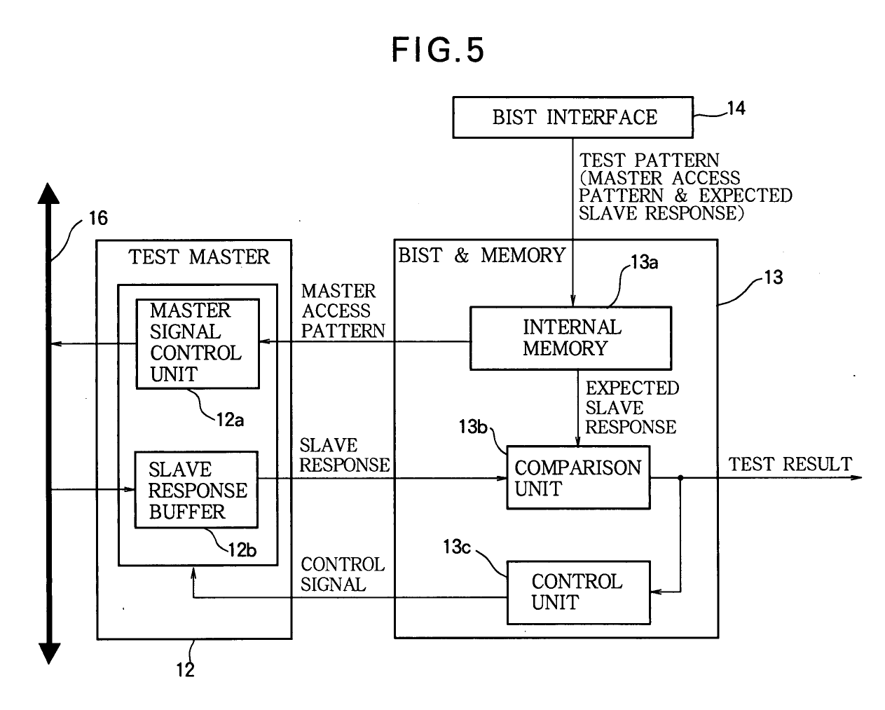

Referring to FIG. 5, the test master circuit 12 includes a master signal control unit 12a and a slave response buffer 12b. The built-in self-test and memory circuit 13 includes an internal memory 13a, a comparison unit 13b, and a control unit 13c. The internal memory 13a receives test patterns from the built-in self-test interface circuit 14 and stores them. A test pattern comprises a pattern of master access signals and the expected slave response pattern. The term ‘test pattern’ will also be used below to mean just the pattern of master access signals. These signals specify an address (addr), write data (wdata), and the type and size of the transfer (the trans and burst signals in the bus protocol). The corresponding expected response pattern includes the expected number of cycles from transmission of the transfer request until completion of the data transfer (the wait time, indicated by arrows in FIG. 4), the expected value of the response signal (resp), and the expected read data (rdata). The master signal control unit 12a reads test patterns (more precisely, master access signal patterns) from the internal memory 13a, converts them to master access signals, and outputs the master access signals on the system bus 16. The slave response buffer 12b receives the response signal, read data, and ready signal output by the accessed device in response to the transfer request and passes them to the comparison unit 13b, which compares them with the expected response values stored in the internal memory 13a and outputs a test result signal. The control unit 13c controls the test master circuit 12 according to the test result signal.

The built-in self-test interface circuit 14 receives test pattern data, including master access patterns and corresponding expected slave response patterns, from an external source such as a host computer system through the serial interface 15 and stores the received data in the internal memory 13a.

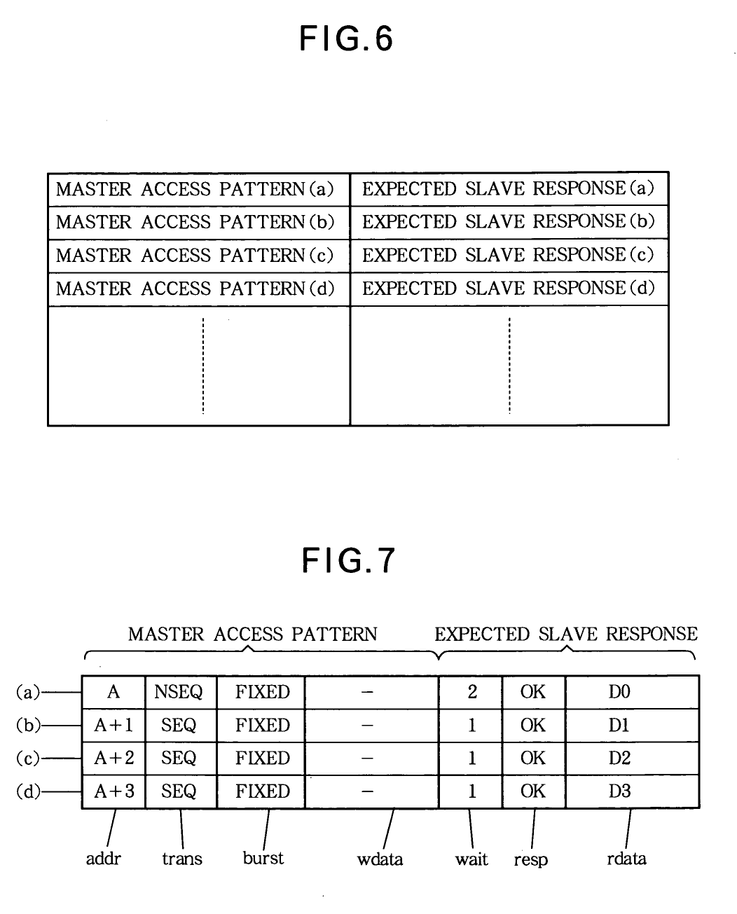

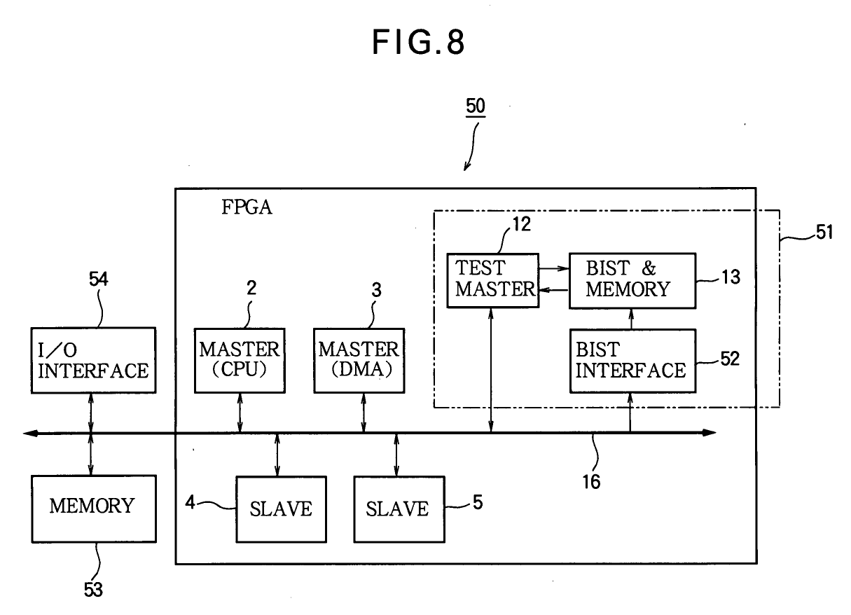

Test master access patterns and expected response values are stored in the internal memory 13a as shown in FIG. 6. The internal memory 13a can store test patterns covering all patterns of access that are possible within the bus protocol described above. Examples of test patterns, including the expected response values, are shown in FIG. 7. The first exemplary test pattern (a) has a non-sequential (NSQ) address (A) and a fixed data size. The accessed device is expected to become ready in two cycles and return read data DO with an OK response signal. The next three test patterns (b-d) are similar except that the addresses (A+1, A+2, A+3) are sequential (SEQ) and the accessed device is expected to become ready in one cycle. These test patterns correspond to the sequence illustrated in FIG. 4.

The verification procedure in the first embodiment proceeds as follows.

First, the FPGA 10 is mounted on a printed circuit board, an in-circuit emulator, or another testing device that provides a connection from the serial interface 15 to a host system. The host system downloads test patterns, including expected response values, which are stored in the internal memory 13a via the built-in self-test interface circuit 14.

Next, the test master circuit 12 is activated. The test master circuit 12 reads the first test pattern from the internal memory 13a, outputs corresponding access signals on the system bus 16, and receives response signals (rdata and resp) from the accessed device. The test master circuit 12 stores the received response signals in its slave response buffer 12b, together with information indicating the number of bus cycles it had to wait to receive the response signals.

The comparison unit 13b then compares the response data stored in the slave response buffer 12b of the test master circuit 12 with the expected response data stored in the internal memory 13a of the built-in self-test and memory circuit 13, and sends the control unit 13c a signal indicating whether or not the received response matches the expected response. This result signal may also be output externally as indicated in FIG. 6. If the received response matches the expected response, the control unit 13c directs the test master circuit 12 to proceed to the next test pattern. If the received response does not match the expected response, the control unit 13c stores the internal memory address of the test pattern that the test master circuit 12 read, then directs the test master circuit 12 to proceed to the next test pattern. Alternatively, the control unit 13c may halt the test master circuit 12 when the received response does not match the expected response.

At the end of the sequence of test patterns, or when the control unit 13c halts the test master circuit 12, the host device can access the system verification circuitry 11 through the built-in self-test interface circuit 14 and serial interface 15 to learn the addresses of the test pattern or patterns that gave unexpected results, and to see what the unexpected response(s) were.

Since the test master circuit 12 is dedicated to testing and is designed to execute all possible access patterns allowed by the bus protocol, and since the internal memory 13a can store any of these test patterns, the test master circuit 12 can emulate the operation of any master device in the FPGA 10. By downloading suitable test patterns, accordingly, the host device can exercise all features of the bus protocol and verify even highly complex system operations without being limited by the capabilities of any particular master device. The slave response buffer 12b can also be made large enough to store all the responses generated in a complex system operation, so that at the end of the operation, the host system can see exactly what happened.

When the test master circuit 12 reads test patterns from the internal memory 13a, it does not use the system bus 16. The system bus 16 only has to carry the master access signals that it would carry during actual operation. Operations involving sequences of accesses can therefore be verified under realistic conditions, uninterrupted by the transfer of test pattern data and associated instructions on the system bus 16.

Moreover, when an operation produces an unexpected result, the conditions that produced the result can be reproduced exactly in a simulation on the host system for detailed analysis. This is particularly easy to do when the sequence of test patterns emulates the operation of a single master device, since the host system only has to run the same sequence of test patterns on a simulated model of the master device. With the invented system verification circuitry 11, this easy case is the most common case: for example, in verifying a direct memory access operation, the test master circuit 12 only has to emulate the operation of the DMA device 3, and not the CPU 2.

Conversely, test patterns that were generated during development of a master device by simulation on the host system can be used without modification to verify the operation of the FPGA 10.

### SECOND EMBODIMENT

Referring to FIG. 5, the FPGA 50 in the second embodiment has the same master devices 2, 3 and slave devices 4, 5 as the first embodiment, and the system verification circuitry 51 in the second embodiment has the same test master circuit 12 and built-in self-test and memory circuit 13, but the built-in self-test interface circuit 52 is now connected to the system bus 16, and the system bus 16 is connected to an external memory 53 and I/O interface device 54. The FPGA 50, memory device 53, and I/O interface device 54 are mounted on a prototype printed circuit board.

The verification procedure is essentially the same as in the first embodiment, except that the host system downloads test patterns through the I/O interface device 54. The test patterns may be transferred from the I/O interface device 54 directly to the internal memory 13a (shown in FIG. 5) of the built-in self-test and memory circuit 13 in the FPGA 50 over the system bus 16, or may be first stored in the memory device 53, then transferred into the internal memory 13a. In either case, after a sequence of test patterns has been stored in the internal memory 13a, it is read by the test master circuit 12 and used to verify the operation of the FPGA 50 in the same way as in the first embodiment, the system bus 16 being used only for output of master access signals by the test master circuit 12 and transfer of the corresponding response signals and data to the test master circuit 12. At the end of a sequence of test patterns, or when the test master circuit 12 is halted because of an unexpected response, the host system can access the system verification circuitry 51 via the I/O interface device 54 and system bus 16 to learn the addresses in the internal memory 13a of test patterns that gave unexpected responses, and to see what the unexpected responses were.

The second embodiment provides the same effects as the first embodiment. System operations can be simulated under realistic conditions, uninterrupted by the transfer of extraneous data on the system bus 16, and when unexpected results are obtained, the conditions that produced the unexpected results can be exactly reproduced in a simulation on the host system for detailed analysis. An advantage of the second embodiment is that test patterns can be loaded and stored faster through the system bus 16 than through the serial interface 15 in the first embodiment.

The invention is not limited to the verification of the operation of an FPGA. Similar system verification circuitry can be provided for an ASIC that is prototyped as a plurality of FPGAs or other integrated circuit chips that emulate the master and slave devices which will be incorporated in the ASIC. In this case, the system bus 16 interconnects the integrated circuit chips, rather than being disposed within a single chip, and the invented verification circuitry may constitute a separate FPGA or other integrated circuit chip connected to the system bus 16. Alternatively, the verification circuitry may be incorporated into a chip that emulates one of the master devices.

Those skilled in the art will recognize that further variations are possible within the scope of the invention, which is defined in the appended claims.

What is claimed is:

1. System verification circuitry for verifying the operation of a system in which a plurality of master devices and at least one slave device are connected to a system bus, comprising:
a test master circuit operable to output test patterns on the system bus for verifying the operation of the at least one slave device, and to receive response signals from the at least one slave device;
a built-in self-test and memory circuit providing the test patterns to the test master circuit and receiving, from the test master circuit, the response signals received by the test master circuit, having an internal memory for storing the test patterns and corresponding expected values, and a comparator for comparing the expected values with the response signals; and
a built-in self-test interface circuit for receiving the test patterns and expected values from an external source and storing the test patterns and expected values in the internal memory in the built-in self-test and memory circuit.

2. The system verification circuitry of claim 1, wherein the test master circuit is operable to output, as said test patterns, all patterns of master access signals that can be output on the system bus by any of the master devices.

3. The system verification circuitry of claim 1, wherein the master devices communicate with the at least one slave device over the system bus by following a predetermined protocol, and the test master circuit is operable to output, as said test patterns, all patterns of master access signals permitted by the predetermined protocol.

4. The system verification circuitry of claim 1, further comprising an external interface circuit for receiving the test patterns and expected values from the external source and passing the test patterns and expected values to the built-in self-test interface circuit.

5. The system verification circuitry of claim 1, further comprising an external interface circuit for receiving the test patterns and expected values from the external source and passing the test patterns and expected values to the built-in self-test interface circuit.

6. The system verification circuitry of claim 5, wherein the external interface circuit is a serial interface circuit.

7. The system verification circuitry of claim 1, wherein the built-in self-test interface circuit receives the test patterns and expected values from the system bus.

8. The system verification circuitry of claim 1, wherein the built-in self-test and memory circuit also has a control unit that stores addresses of test patterns in the internal memory that produce response signals not matching the expected values.

9. The system verification circuitry of claim 8, wherein the control unit halts the test master circuit when the test master circuit receives response signals not matching the expected values.

10. The system verification circuitry of claim 8, wherein the control circuit sends a signal to the external source, indicating whether the received response signals match the expected values.

11. The system verification circuitry of claim 1, wherein the system verification circuitry is disposed in a monolithic integrated circuit together with the plurality of master devices and the at least one slave device.

12. The system verification circuitry of claim 11, wherein the monolithic integrated circuit is a field-programmable gate array.

13. The system verification circuitry of claim 1, wherein the master devices and the at least one slave device are disposed in a plurality of integrated circuits interconnected by the system bus, and the system verification circuitry is disposed in one of the integrated circuits.

14. The system verification circuitry of claim 1, wherein the master devices and the at least one slave device are disposed in a plurality of integrated circuits interconnected by the system bus, and the system verification circuitry is disposed in a separate monolithic integrated circuit connected to the system bus.
